(19) United States
(12) Patent Application Publication
(10) Pub. No.: US 2008/0310089 A1
(43) Pub. Date: Dec. 18, 2008

(54) HOUSING ASSEMBLY FOR PORTABLE ELECTRONIC DEVICE

(75) Inventor: MIN-SHENG WANG, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: CHI MEI COMMUNICATION SYSTEMS, INC., Tu-Cheng City (TW)

(21) Appl. No.: 11/952,959

(22) Filed: Dec. 7, 2007

(30) Foreign Application Priority Data
Jun. 13, 2007 (CN) 200710075033.2

(51) Int. Cl. H05K 5/00

(52) U.S. Cl. 361/680

(57) ABSTRACT

A housing assembly (22) for use in a portable electronic device (20), includes a keypad board (221), a circuit board (223), and a main body (224). The keypad board has at least one key (2211) formed at a top surface thereof and at least one mounting pin (2224) formed at a bottom surface thereof. The circuit board has at least one swithpoint (2233) formed thereon. Each of the swithpoint corresponds to the at least one key. The main body defines a mounting cavity (2248) in one side thereof. The keypad board and the circuit board are mounted in the mounting cavity from top to bottom with the at least one mounting pin.

### BACKGROUND OF THE INVENTION

1. Field of the Invention

The present invention generally relates to housing assemblies, and specifically to a housing assembly of a portable electronic device, such as a mobile telephone.

2. Description of Related Art

With the development of wireless communication and information processing technologies, portable electronic devices, such as mobile telephones and electronic notebooks, are now in widespread use. These portable electronic devices enable consumers to enjoy high technology services, anytime and anywhere. The developing trend of these portable electronic devices is to be light, thin, short, and small in volume.

A typical housing assembly for a given portable electronic device includes an upper shell, a keypad board, a circuit board, and a lower shell. The upper shell defines a hole therethrough. The keypad board is provided with plurality of keys thereon. The circuit board is provided with plurality of switchpoints thereon. In assembly, the keypad board is mounted in the upper shell and the keys are exposed through the hole of the upper shell. The circuit board is mounted in the lower shell. The upper shell is mounted to the lower shell and each switchpoint corresponds to a key. The key is pressed downward so as to make contact with a corresponding switchpoint, thereby generating an input signal. However, such a housing assembly has a relative large volume.

Therefore, a new housing assembly is desired in order to overcome the above-described problems.

### SUMMARY

In one aspect thereof, a housing assembly for a portable electronic device, includes a keypad board, a circuit board, and a main body. The keypad board has at least one key formed at a top surface thereof and at least one mounting pin formed at a bottom surface thereof. The circuit board has at least one swithpoint formed thereon. Each of the swithpoint corresponds to the at least one key. The main body defines a mounting cavity in one side thereof. The keypad board and the circuit board are mounted in the mounting cavity from top to bottom with the at least one mounting pin.

Other advantages and novel features of the embodiments will become more apparent from the following detailed description thereof, when taken in conjunction with the accompanying drawings.

### BRIEF DESCRIPTION OF THE DRAWINGS

Many aspects of the present housing assembly can be better understood with reference to the following drawings. The components in the drawings are not necessarily drawn to scale, the emphasis instead being placed upon clearly illustrating the principles of the present housing assembly and its potential applications. Moreover, in the drawings, like reference numerals designate corresponding parts throughout the several views.

FIG. 1 is an exploded, isometric view of a portable electronic device having a housing assembly, in accordance with a present embodiment;

FIG. 2 is a partially assembled, isometric view of the portable electronic device shown in FIG. 1;

FIG. 3 is another partially assembled, isometric view of the portable electronic device shown in FIG. 1; and

FIG. 4 is an assembled, isometric view of the portable electronic device shown in FIG. 1.

### DETAILED DESCRIPTION OF THE EMBODIMENTS

The present housing assembly is suitable for portable electronic devices, such as mobile phones, PDAs, and the like. Other applications with similar housing employed can also be found.

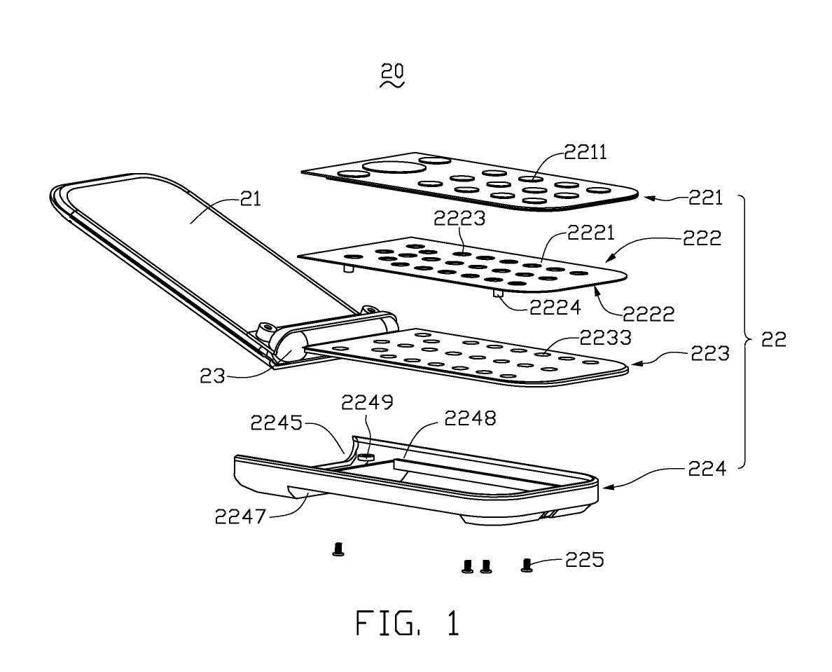

Referring now to the drawings in detail, FIG. 1 shows a portable electronic device 20 employing the present housing assembly 22. The portable electronic device 20 further includes a cover 21 and a hinge mechanism 23. The housing assembly 22 is interconnected to the cover 21 by the hinge mechanism 23.

The housing assembly 22 includes a keypad board 221, a supporting board 222, a circuit board 223, a main body 224, and at least one bolts 225. The keypad board 221, the supporting board 222, and the circuit board 223 are mounted to the main body 224 from top to bottom by the at least one bolts 225.

The keypad board 221 is a substantially rectangular flat board in shape. At least one key 2211 is formed at one side of the keypad board 221.

The supporting board 222 is a substantially rectangular flat board in shape. The size of the supporting board 222 is substantially the same as that of the keypad board 221. The supporting board 222 has a top surface 2221 and a bottom surface 2222 opposite to the top surface 2221. At least one through hole 2223 is defined through the top surface 2221 and the bottom surface 2222. Each through hole 2223 is configured (i.e., structured and arranged) for corresponding to a key 2211 of the keypad board 221. At least one mounting pin 2224 is formed on the bottom surface 2222.

The circuit board 223 is a substantially rectangular flat board in shape. The size of the circuit board 223 is smaller than that of the supporting board 222. At least one switchpoint 2233 is formed at one side of the circuit board 223. Each switchpoint 2233 is configured for corresponding to a key 2211 of the keypad board 221 and a through hole 2223 of the supporting board 222.

The main body 224 is a substantially rectangular block in shape and defines a receiving cavity 2245 in a distal end thereof. The hinge mechanism 23 is configured for being receivable in the receiving cavity 2245. The main body 224 defines a mounting cavity 2248 on one side thereof and defines a battery cavity 2247 on an opposite side thereof. The mounting cavity 2248 communicates with the battery cavity 2247. The mounting cavity 2248 is configured to receive the keypad board 221, the supporting board 222, and the circuit board 223 therein. The battery cavity 2247 is configured to receive a battery (not shown) therein in order to produce electric energy for the portable electronic device 20. At least one mounting hole 2249 is defined in the main body 224. Each mounting hole 2249 is configured to engage with a corresponding mounting pin 2224 thereby mounting the supporting board 222 to the main body 224 by each bolt 225 being bolted in a corresponding mounting pin 2224.

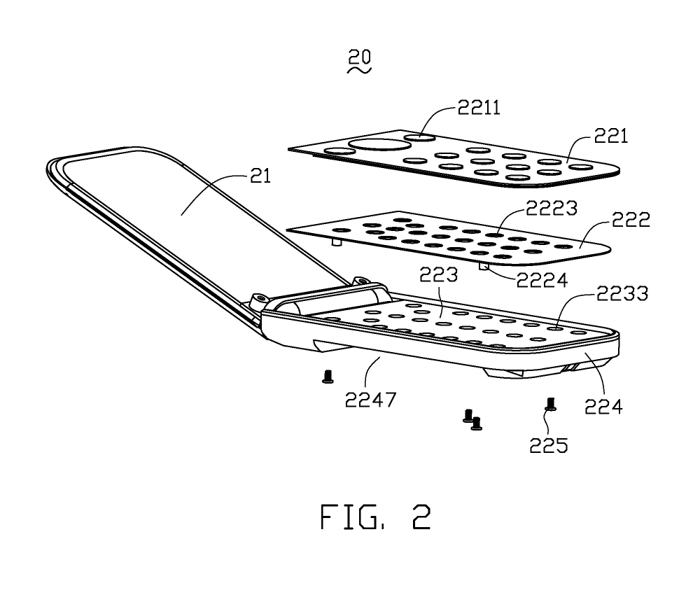

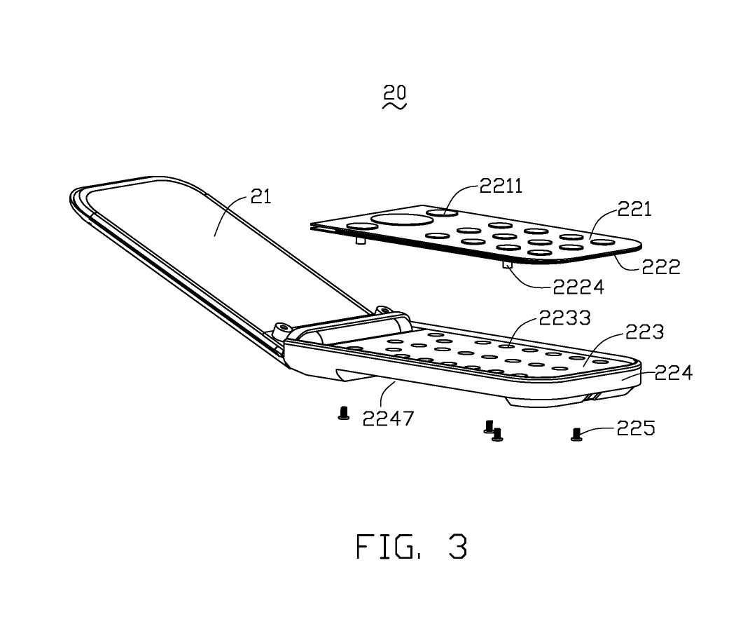

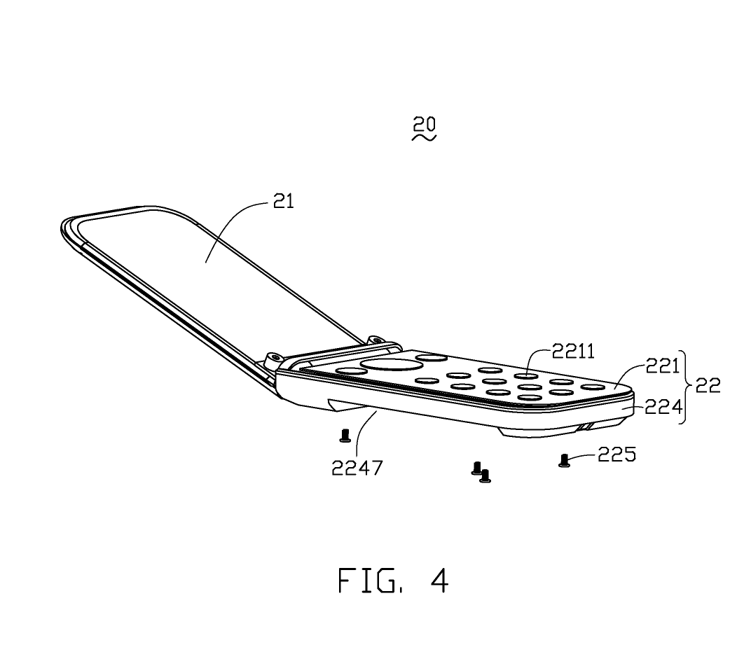

Also referring to FIGS. 2-3, in assembly, the supporting board 222 is mounted to a side opposite to the at least one key 2211 of the keypad board 221. Each through hole 2223 corresponds to a key 2211. The circuit board 223 is mounted into the mounting cavity 2248 of the main body 224. The fixed keypad board 221 and supporting board 222 are mounted into the mounting cavity 2248 with each mounting pin 2224 traveling through a corresponding through hole and each bolt being bolted in a corresponding mounting pin 2224. Each switchpoint 2233 corresponds to a key 2211 of the keypad board 221 and a through hole 2223 of the supporting board 222. Thus, the portable electronic device 20 is completely assembled, as represented in FIG. 4. In use, the key is pressed downward so as to make contact with a corresponding switchpoint, thereby generating an input signal.

It should be understood that the supporting board 222 may be omitted and the mounting pin 2224 is formed on the keypad board 221.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A housing assembly for portable electronic device, comprising:
a keypad board having at least one key formed at a top surface thereof and provided with at least one mounting pin formed at a bottom surface thereof;
a circuit board having at least one swithpoint formed thereon, the at least one swithpoint corresponding to the at least one key; and
a main body defining a mounting cavity in one side thereof, the keypad board and the circuit board being mounted in the mounting cavity from top to bottom in that turn, the at least one mounting pin being mounted to the main body.

2. The housing assembly as claimed in claim 1, further comprising a supporting board, wherein the supporting board is configured for being mounted to the bottom surface of the keypad board, and the at least one mounting pin is formed at the supporting board.

3. The housing assembly as claimed in claim 2, wherein the supporting board defines at least one through hole therethrough and the at least one through hole corresponds to the at least one swithpoint and the at least one key.

4. The housing assembly as claimed in claim 1, wherein each of the keypad board and the circuit board is a substantially rectangular flat board in shape, and the size of the circuit board is smaller than that of the keypad board.

5. The housing assembly as claimed in claim 4, wherein the main body is a substantially rectangular block in shape.

6. The housing assembly as claimed in claim 5, wherein the main body defines at least one mounting hole therein for receiving the at least one mounting pin therein.

7. The housing assembly as claimed in claim 6, wherein the at least one mounting pin is mounted to the main body with at least one bolt.

8. The housing assembly as claimed in claim 5, wherein the main body defines a battery cavity in another side opposite to the side defining the mounting cavity, and the mounting cavity communicates with the battery cavity.
